(19) United States
(12) Patent Application Publication
(10) Pub. No.: US 2019/0385810 A1
(43) Pub. Date: Dec. 19, 2019

(54) Charged Particle Beam Device

(71) Applicant: Hitachi High-Technologies Corporation, Minato-ku, Tokyo (JP)

(72) Inventors: Ryuju SATO, Tokyo (JP); Toshihide AGEMURA, Tokyo (JP); Tsunenori NOMAGUCHI, Tokyo (JP)

(73) Assignee: Hitachi High-Technologies Corporation, Minato-ku, Tokyo (JP)

(21) Appl. No.: 16/487,566

(22) PCT Filed: Feb. 22, 2017
(86) PCT No.: PCT/JP2017/006449

§ 371 Date: Aug. 21, 2019

(51) Int. Cl. H01J 37/244; H01J 37/28

(52) U.S. Cl. CPC H01J 37/244; H01J 37/05; H01J 37/28

(57) ABSTRACT

The charged particle beam device includes a charged particle beam source which emits a primary charged particle beam, an objective lens which focuses the primary charged particle beam on a sample, a passage electrode which is formed of a metal material and is disposed between the charged particle beam source and a tip end of the objective lens, a detector which detects a secondary charged particle emitted from the sample, and an electrostatic field electrode which is electrically insulated from the passage electrode. The passage electrode is formed such that the primary charged particle beam passes through the inside of the passage electrode. The electrostatic field electrode is formed to cover an outer periphery of the passage electrode.

### TECHNICAL FIELD

The present invention relates to a charged particle beam device.

### BACKGROUND ART

A technique for discriminating and detecting secondary electrons and backscattered electrons in a charged particle beam device is disclosed (PTL 1). In PTL 1, a deceleration space for decelerating signal electrons is provided in a detection system and a deflection field is generated in this deceleration space, so that secondary electrons having low energy are selectively collected. Further, the energy of the signal electrons to be detected is selected by controlling a potential of the deceleration space.

### PRIOR ART LITERATURE

### Patent Literature

PTL 1: WO99/46798

### SUMMARY OF INVENTION

### Technical Problem

In the detection system including the deceleration space as described in PTL 1, the deflection field leaks onto a primary electron beam path, and accordingly an increase in aberration due to energy dispersion of the primary electron beam cannot be avoided. Here, when the deflection field is weakened to reduce the influence on the primary electron beam track, the collection efficiency of the secondary electrons is reduced. That is, aberration reduction of the primary electron beam and high efficiency detection of the signal electrons cannot be both achieved.

Therefore, an object of the present invention is to provide a charged particle beam device which can efficiently collect emitted particles generated in a sample by discriminating energy without influence on the primary particle beam.

### Solution to Problem

A charged particle beam device includes a charged particle beam source which emits a primary charged particle beam, an objective lens which focuses the primary charged particle beam on a sample, a passage electrode which is formed of a metal material and is disposed between the charged particle beam source and a tip end of the objective lens, a detector which detects a secondary charged particle emitted from the sample, and an electrostatic field electrode which is electrically insulated from the passage electrode. The passage electrode is formed such that the primary charged particle beam passes through the inside of the passage electrode. The electrostatic field electrode is formed to cover an outer periphery of the passage electrode.

### Advantageous Effect

According to the invention, it is possible to provide a charged particle beam device which can efficiently collect emitted particles generated in a sample by discriminating a energy without influence on the primary particle beam.

### BRIEF DESCRIPTION OF DRAWINGS

FIG. 1 is a schematic diagram of a scanning electron microscope (SEM) according to a first embodiment.

FIGS. 2A to 2C illustrate a configuration of a secondary electron detector.

FIGS. 3A to 3C are schematic diagrams of an aperture.

FIG. 4 is a schematic diagram of an ET detector.

FIG. 5 is a diagram in which secondary electron detectors are provided in four directions.

FIG. 6 is a schematic diagram of an SEM according to a second embodiment.

FIG. 7 is a diagram in which secondary electron detectors according to the second embodiment are provided in four directions.

FIG. 8 is a schematic diagram of an SEM according to a third embodiment.

FIG. 9 is a cross-sectional schematic diagram of a passage electrode.

FIG. 10A is a schematic diagram of a potential distribution when no high-resistance material according to the third embodiment is provided.

FIG. 10B is a schematic diagram of a potential distribution when the high-resistance material according to the third embodiment is provided.

FIG. 11 is a schematic diagram of a beam electrode.

FIG. 12 is a schematic diagram of an SEM according to a forth embodiment.

FIG. 13 is a schematic diagram of an SEM according to a fifth embodiment.

FIG. 14 is a schematic diagram of an FIB-SEM.

FIG. 15 illustrates an example of a monitor screen.

### DESCRIPTION OF EMBODIMENTS

In the following embodiments, an example of a charged particle beam device is not limited to a scanning electron microscope (hereinafter referred to as “SEM”), and can be applied to, for example, a focused ion beam scanning electron microscope (hereinafter referred to as “FIB-SEM”) and a scanning transmission electron microscope (STEM).

The SEM is a device which obtains a two-dimensional scanned image by accelerating a primary electron beam emitted from an electron source, two-dimensionally scanning a sample and detecting signal electrons generated from the sample. When the sample is irradiated with the primary electron beam, the primary electron beam is narrowed down by using an objective lens. The primary electron beam can be further narrowed as aberration of the objective lens becomes smaller, so that the sample can be observed with a higher resolution. That is, the aberration of the objective lens is preferably smaller.

On the other hand, recent years have seen an increasing observation demand at a low acceleration voltage for the purpose of observing a top surface of a sample or reducing damages to a sample. In general, when the acceleration voltage drops, the aberration of the objective lens increases and the resolution of an SEM image deteriorates. This is a major cause of increased chromatic aberration due to the low energy of the primary electron beam as it passes through the objective lens.

In order to achieve a high resolution even at the low acceleration voltage, an optical system (hereinafter, referred to as a deceleration optical system) which decelerates the primary electron beam before reaching the sample is effective. In the deceleration optical system, since the primary electrons pass through the objective lens with high energy, the chromatic aberration can be reduced.

As a method for realizing the deceleration optical system, a retarding method and a boosting method are used. In both methods, a potential gradient is provided so that the primary electron beam is decelerated between the sample and an SEM body, but portions to which voltages are applied are different. In the retarding method, a negative voltage is applied to the sample. In the boosting method, an electrode (hereinafter referred to as a boosting electrode) through which a primary electron beam passes is provided in the SEM body, and a positive voltage is applied to the electrode. A high resolution at the low acceleration voltage is realized by these methods.

In addition, signal electrons detected by the SEM are roughly classified into two kinds. One is a secondary electron with low energy (typically 50 eV or less) and the other is a backscattered electron with high energy (typically from 50 eV to irradiation energy of the primary electron beam). A secondary electron image mainly shows a contrast which reflects a surface shape of the sample. On the other hand, in case of the backscattered electron, contrast obtained by that energy is different. An image in which a part of backscattered electrons having energy to an extent of the irradiation energy of the primary electron beam is detected shows a contrast which reflects the surface shape and a composition distribution of the sample. When backscattered electrons with relatively low energy are detected, information including the composition and structure inside the sample is reflected in the contrast of the image. As described above, various sample information can be obtained by detecting the signal electrons and classifying each of them by energy.

In a normal optical system, for example, only secondary electrons with low energy can be deflected and detected by a deflector. However, in the deceleration optical system, the secondary electrons and the backscattered electrons have high energy by being accelerated by a potential difference between the sample and the SEM body. Since it is difficult to deflect only the secondary electrons with high energy, PTL 1 is proposed as a method for solving the problem. However, as described above, PTL 1 cannot achieve both aberration reduction of the primary electron beam and high efficiency detection of the secondary electrons. Therefore, embodiments for solving this problem will be described below.

### First Embodiment

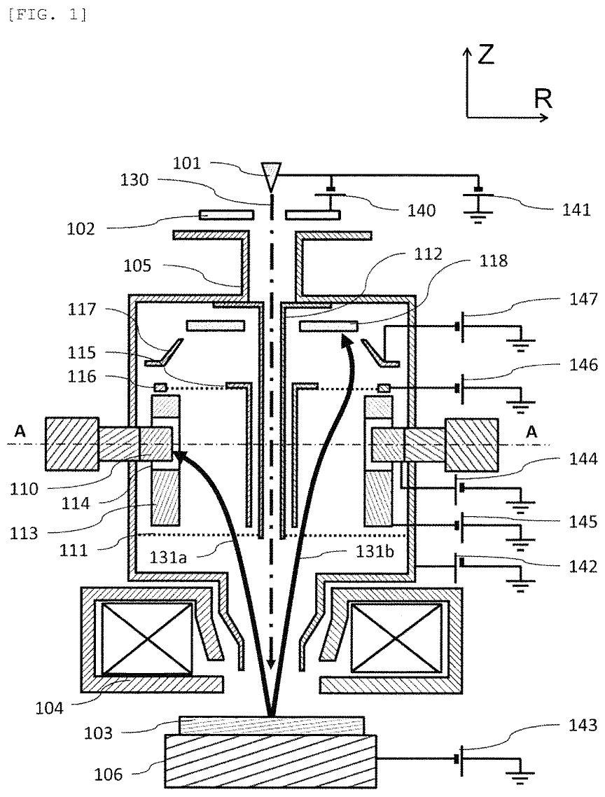

FIG. 1 is a schematic view of an SEM according to the first embodiment. As shown in FIG. 1, a Z-axis represents an axis parallel to a path through which a primary electron beam passes, and an R-axis represents an arbitrary axis defined on a plane perpendicular to the Z-axis.

The SEM in FIG. 1 includes an electron source 101 which generates a primary electron beam 130, an extraction electrode 102 which extracts electrons from the electron source 101, an objective lens 104 which focuses the primary electron beam 130 on a sample 103, a boosting electrode 105 which accelerates the primary electron beam 130, a sample holder 106 on which the sample 103 is placed, a secondary electron detector 110 which detects secondary electrons 131a generated in the sample 103, a passage electrode 112 which surrounds a path of the primary electron beam 130 and is in contact with the boosting electrode 105, an extraction power supply 140 which applies an extraction voltage between the electron source 101 and the extraction electrode 102, an acceleration power supply 141 which applies an acceleration voltage to the electron source 102 to accelerate the primary electron beam, a boosting power supply 142 which applies a positive voltage to the boosting electrode 105 and the passage electrode 112, and a retarding power supply 143 which applies a negative voltage to the sample holder 106 and the sample 103.

Although FIG. 1 illustrates an example in which a boosting method of applying a positive voltage to the boosting electrode 105 and a retarding method of applying a negative voltage to the sample 103 are combined, a method of realizing a deceleration optical system is not limited thereto. That is, either the boosting method or the retarding method may be used.

The secondary electron detector 110 is disposed between the electron source 102 and the sample 103. The SEM further includes: a first grid electrode 111 having a mesh structure through which signal electrons enter between the secondary electron detector 110 and the objective lens 104; a first electrostatic field electrode 113, a second electrostatic field electrode 115, and a second grid electrode 116 having a mesh structure which are disposed between the electron source 102 and the first grid electrode 111 and are electrically insulated from the passage electrode 112; a track control electrode 117 which controls the track of the signal electrons and is disposed between the electron source 101 and the secondary electron detector 110; and a backscattered electron detector 118 which detects backscattered electrons 131 and is disposed between the electron source 101 and the track control electrode 117.

In order to apply a voltage to each electrode, the following power supplies, that is, a detector power supply 144 which supplies a positive voltage to the secondary electron detector 110, a first deceleration power supply 145 which supplies a negative voltage to the first electrostatic field electrode 113, a second deceleration power supply 146 which supplies a negative voltage to the second electrostatic field electrode 115 and the second grid electrode 116, and a track control power supply 147 which supplies a negative voltage to the track control electrode 117 are respectively connected. Here, a potential approximately the same as the sample is applied to the first deceleration power supply 145 and the second deceleration power supply 146. Hereinafter, an electric field area, which is formed of the first electrostatic field electrode 113, the second electrostatic field electrode 115 and the second grid electrode 116 to decelerate the signal electrons, is referred to as a deceleration space.

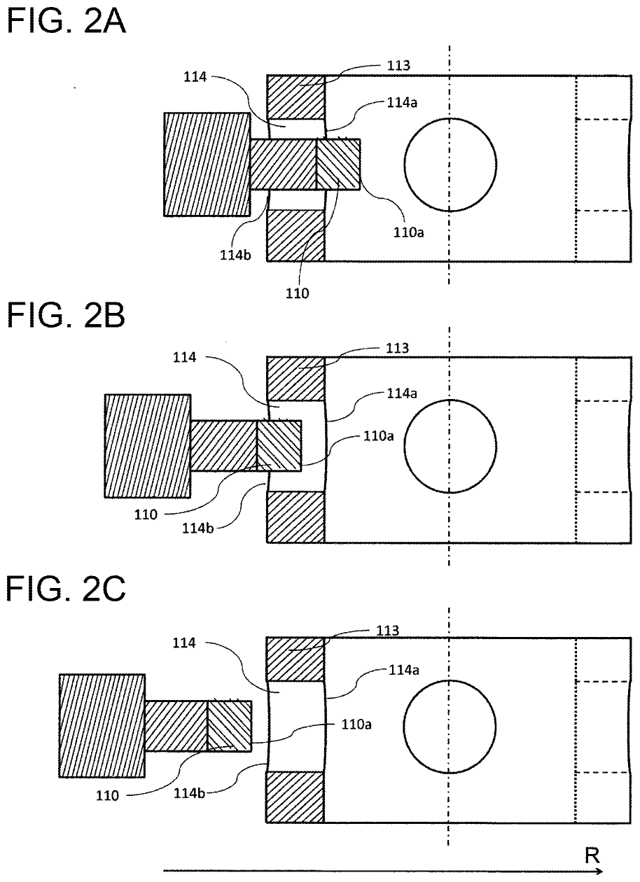

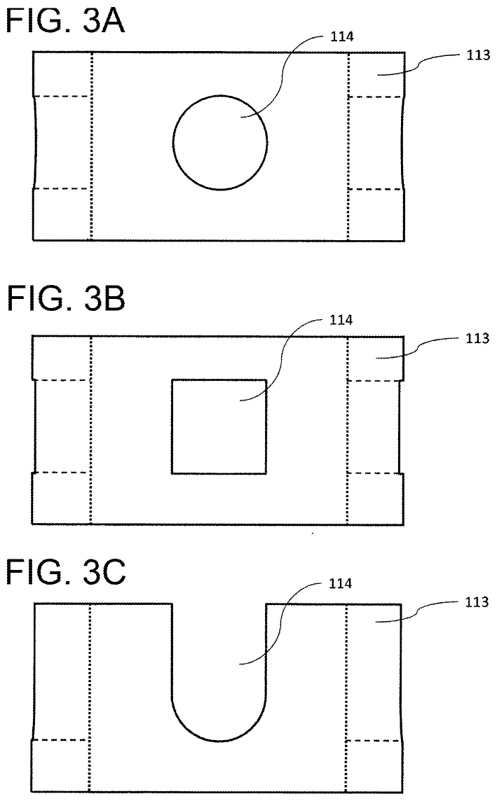

FIGS. 2A to 2C illustrate configurations of the secondary electron detector. In the first electrostatic field electrode 113, an aperture 114 including a tip surface 114a on the side close to the passage electrode 112 and a tip surface 114b on the side away from the passage electrode 112 is provided on a side wall thereof, and the secondary electron detector 110 faces the aperture 114. That is, a sensitive face 110a of the secondary electron detector 110 faces the deceleration space. For example, the sensitive face 110a is closer to the side of the passage electrode 112 (FIG. 2A) than the tip surface 114a in the R-axis direction, or in the aperture 114 (FIG. 2B), or in a direction further away from the passage electrode 112 than the tip surface 114b in the R-axis direction (FIG. 2C). Further, the sensitive face 110a also may overlap the tip surfaces 114a and 114b. In addition, although the sensitive face 110a is preferably parallel to the axis of the passage electrode 112, it may also be slightly inclined within a range in which the secondary electrons can be efficiently obtained.

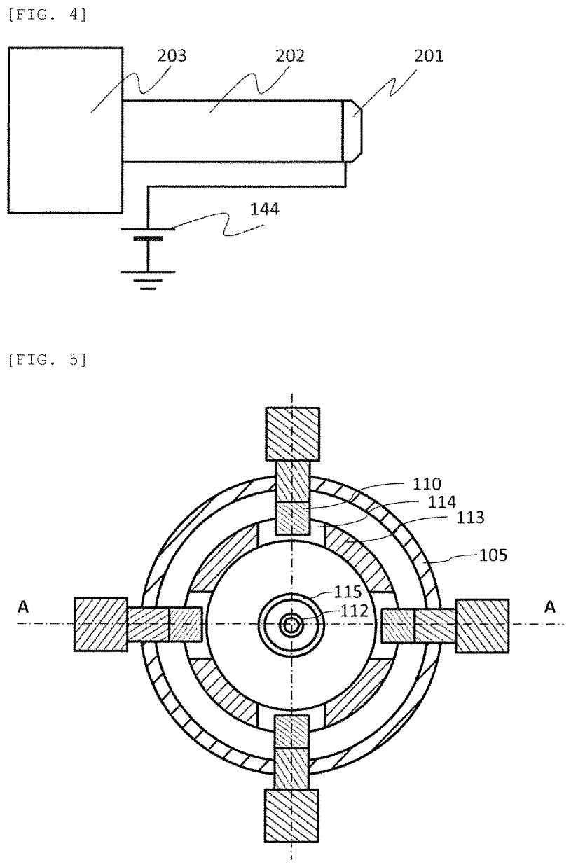

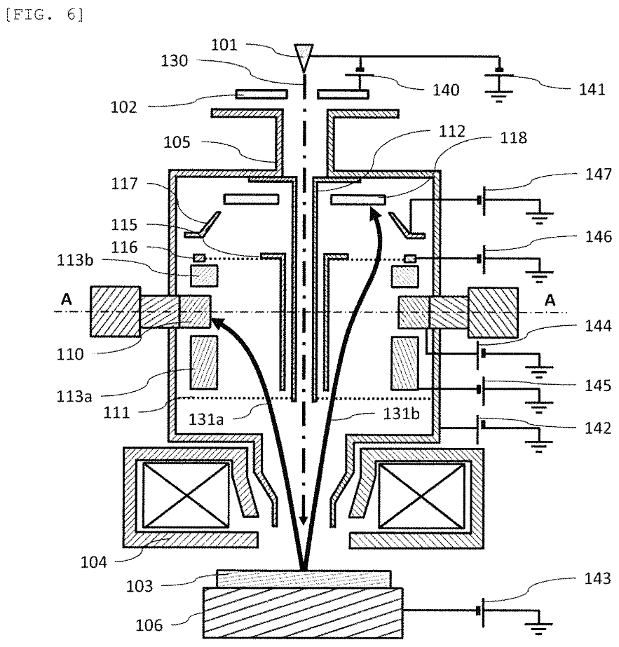

A strong deflection field is formed in the deceleration space through the aperture 114, so that a part of the signal electrons are guided to the secondary electron detector 110. FIGS. 3A to 3C are schematic views of the aperture. FIGS. 3A to 3C show three types of a round-hole (FIG. 3A), a square-hole (FIG. 3B) and a structure (FIG. 3C) cutting out in the end portion direction, but the present invention is not limited thereto.

Next, an operation principle of the SEM illustrated in FIG. 1 will be described. The primary electron beam 130 emitted from the electron source 101 passes through the passage electrode 112, and is narrowed down by the objective lens 104 and applied to the sample 103. When the primary electron beam 130 is applied to the sample 103, the signal electrons such as the secondary electrons 131a and the backscattered electrons 131b are emitted. The signal electrons are accelerated by the retarding voltage and the boosting voltage to travel toward the electron source 101, and pass through the first grid electrode 111. The signal electrons guided to the deceleration space are decelerated again to the same extent of energy at the time of being generated on the sample 103. In the deceleration space, the secondary electrons 131a with low energy in the signal electrons are highly efficiently collected by the strong deflection field, and are highly efficiently detected by the secondary electron detector 110. On the other hand, the backscattered electrons 131b still have higher energy even when decelerated. Accordingly, the backscattered electrons 131b pass through the deceleration space, tracks thereof are corrected by the track control electrode 117, and the backscattered electrons 131b are highly efficiently detected by the backscattered electron detector 118.

Further, by shielding an electric field leakage to the path of the primary electron beam 130, the strong deflection field can be formed in the deceleration space without influence on the primary electron beam 130, and the secondary electrons 131a can be highly efficiently detected. Thus, the signal electrons are collected and discriminated into the secondary electrons 131a and the backscattered electrons 131b, and difficulties of aberration reduction of the primary electron beam 130 and high efficiency detection of the secondary electrons 131a are overcome.

Further, in this embodiment, a voltage which decelerates the signal electrons by the retarding voltage and the boosting voltage is applied to the first electrostatic field electrode 113, the second electrostatic field electrode 115 and the second grid electrode 116, so that the deceleration space is formed. Of course, in case of an optical system to which only the retarding method or the boosting method is applied, the deceleration space can be similarly formed by applying a voltage which decelerates the signal electrons by one voltage to the electrode. Further, in an optical system to which the retarding method and the boosting method are not applied, only the secondary electrons 131a can be selectively detected by the deflection field without applying a voltage to each electrode. In this case, the deceleration space isnot formed. An embodiment to which the deceleration optical system is not applied will be described below (FIG. 8).

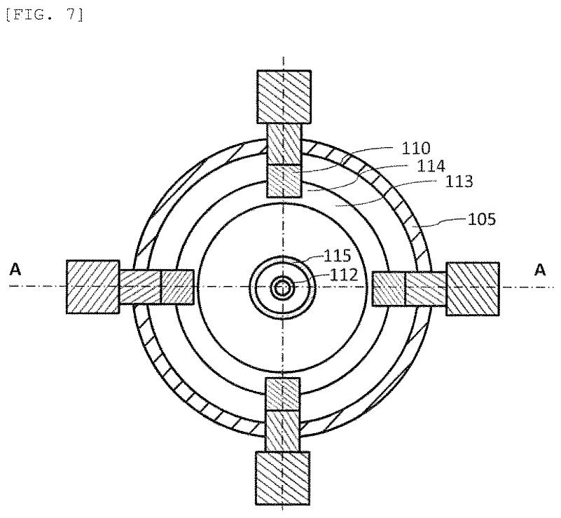

The deflection field which guides the secondary electrons 131a to the secondary electron detector 110 can be easily formed, for example, by using an Everhart-Thornley detector (ET detector) having a scintillator (sensitive face 110a), a light guide and a photo-electron multiplier tube in the secondary electron detector 110. FIG. 4 is a schematic view of the ET detector. The detector includes a scintillator 201 which converts collided electrons into light, a light guide 202 which transmits the light, and a photo-electron multiplier tube 203 which multiplies and converts the reached light into an electrical signal. The detector power supply 144 applies a high voltage (for example, 10 kV) to the scintillator 201. Accordingly, a strong electric field in the horizontal direction is formed in the deceleration space, and the secondary electrons 131a can be guided to the secondary electron detector 110. Further, when the boosting voltage is a high voltage (for example, 8 kV), the detector power supply 144 is unnecessary by making the boosting electrode 105 and the scintillator 201 conductive. In addition, there is no limitation on the above method of forming the deflection field. For example, a mesh-like electrode may be disposed between the scintillator 201 and the first electrostatic field electrode 113, so that it does not matter even when the secondary electrons 131a is deflected toward the secondary electron detector 110 by applying a positive voltage to the mesh-like electrode.

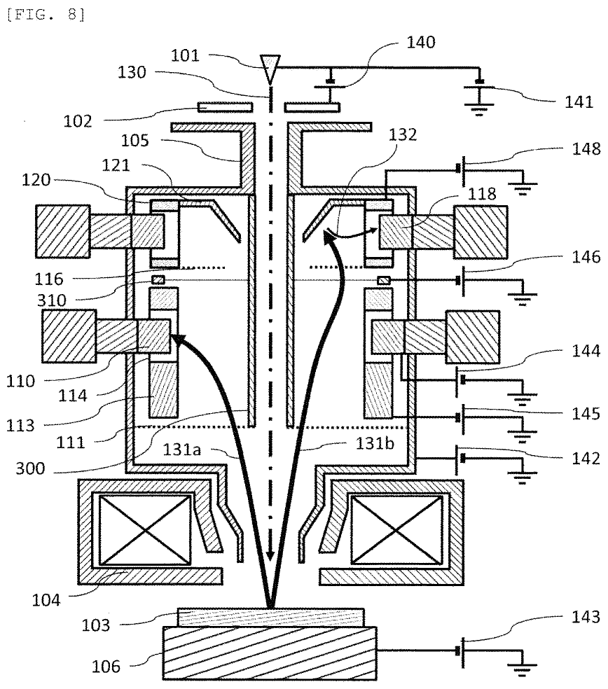

FIG. 5 is a diagram in which secondary electron detectors are provided in four directions. Although a setting number of secondary electron detectors 110 is not limited, the collection efficiency changes depending on the position at which the secondary electrons 131a enter when the setting number is small (for example, only one). That is, in the secondary electrons 131a which enter the deceleration space in the direction in which the secondary electron detector 110 is disposed and the secondary electrons 131a which enter the deceleration space in the opposite direction with the passage electrode 112 in between, the former is much easier to detect. Therefore, unevenness of brightness depending on a generation position of the secondary electrons 131a on the sample is generated in an observation image obtained from the secondary electron detector 110 in one direction. In order to reduce the unevenness, it is required to reduce deviations of the collection efficiency of the secondary electrons 131a. Therefore, by using an electric circuit which includes the secondary electron detectors 110 in a plurality of directions and appropriately processes a signal obtained from each detector, it is possible to obtain an image in which unevenness of brightness is reduced. It has been found from an electronic track simulation study that it is preferable to dispose detectors in three directions or more.

Further, by disposing the secondary electron detector 110 in a plurality of directions, discrimination depending on emission angles of the secondary electrons 131a can be performed. By this emission angle discrimination, an image in which an uneven structure on a surface of the sample is emphasized can be obtained. When the surface of the sample to be observed has an uneven structure or a structure inclined with respect to an irradiation axis of the primary electron beam 130, distribution of the emission angle of the signal electrons is asymmetric with respect to the irradiation axis. That is, the signal electrons are emitted in a deviated manner with respect to a part of an angle direction. By using this deviation and selectively detecting signal electrons in a part of the angle direction, it is possible to obtain the image in which the uneven structure on the surface of the sample is emphasized.

In this embodiment, the secondary electrons 131a can be obtained according to emission angles by the secondary electron detectors 110 disposed in four directions. Therefore, by forming an image based on only the signal obtained from any one of the secondary electron detectors 110, a contrast in which the above uneven structure is emphasized can be obtained. Further, by subtracting the signal from the secondary electron detectors 110 which are facing each other, it is possible to obtain the contrast which further emphasizes the unevenness or the inclined surface of the sample. In addition, when an image is formed by adding the signals obtained by the four secondary electron detectors 110, the contrast other than the uneven structure is likely to appear more clearly.

As the backscattered electron detector 118, for example, the ET detector having a ring shape is used. In this case, since a high voltage is applied to the scintillator in the same manner as the secondary electron detector 110, it is necessary to control the potential of the deceleration space so that the secondary electrons 131a are not drawn by this high voltage. Here, there is no limitation on the method of detecting the backscattered electrons 131b. The detection may be performed using a semiconductor detector having the ring shape, and a configuration, in which a conversion electrode is disposed to detect converted electrons generated when the backscattered electrons 131b collide thereon, may be adopted. An embodiment using the conversion electrode will be described below (FIG. 8).

Here, the backscattered electrons 131b can pass through opening parts of the mesh in the second grid electrode 116 to reach the backscattered electron detector 118. Therefore, by increasing the ratio (opening ratio) of the area of the opening parts with regards to the mesh, the backscattered electrons 131b passing through the second grid electrode 116 can be increased. On the other hand, the potential of the track control electrode 117 and the backscattered electron detector 118 leaks into the deceleration space more easily as the opening ratio of the second grid electrode 116 is higher, so that the track of the secondary electrons 131a is influenced. When the ET detector is used as the backscattered electron detector 118, the high voltage applied to the scintillator 201 leaks into the deceleration space. When the leakage amount is large, the secondary electrons 131a pass through the deceleration space and are detected by the backscattered electron detector 118. Therefore, it is desirable that the opening ratio of the second grid electrode 116 is determined by a detection balance between the secondary electrons 131a and the backscattered electrons 131b.

When the passage electrode 112 is exposed to the deceleration space, an electric field is generated in the deceleration space such that the signal electrons receive a force in the direction of the passage electrode 112. Then, the secondary electrons 131a which enter the deceleration space from the vicinity of the passage electrode 112 are attracted to the passage electrode 112, and thus many of the secondary electrons 131a are not detected. In order to overcome this, in this configuration, the second electrostatic field electrode 115 is disposed directly outside the passage electrode 112 to prevent an electric field which attracts the secondary electrons 131a from being generated in the deceleration space. With the above configuration, both aberration reduction of the primary electron beam 130 and high efficiency detection of the secondary electrons 131a can be achieved.

Here, it is not necessary to respectively apply the same voltage to the first electrostatic field electrode 113, the second electrostatic field electrode 115 and the second grid electrode 116. However, since the second electrostatic field electrode 115 is disposed inner than the first electrostatic field electrode 113, it is necessary to apply a voltage to the second electrostatic field electrode 115 from an outer side than the first electrostatic field electrode 113. As a method of applying the voltage, the second grid electrode 116 is brought into contact with the second electrostatic field electrode 115 to have the same potential, and the structure can be simplified as shown in FIG. 1. Also in this case, the second grid electrode 116 and the second electrostatic field electrode 115 are not required to have the same potential as the first electrostatic field electrode 113.

Here, different voltages are respectively applied to the passage electrode 112 and the second electrostatic field electrode 115. Therefore, it is necessary to maintain an appropriate distance so that discharge does not occur therebetween. On the other hand, in order to guide a number of signal electrons as large as possible into the deceleration space, the second electrostatic field electrode 115 is required to have an outer diameter as small as possible. Considering that the inner diameter of the passage electrode 112 needs to be greater than or equal to a certain value in order to allow the primary electron beam 130 to pass, it is desired to optimize a design of these electrodes by weighing the risk of discharge and the collection efficiency of signal electrons in the balance.

Further, since the path of the primary electron beam 130 is separated from the deceleration space by the passage electrode 112, the influence of the primary electrons 130 due to a space potential formed by the deceleration space or the scintillator is mitigated. Here, in order to minimize the influence of the primary electrons 130, the passage electrode 112 needs to be long enough to prevent the potential of the deceleration space or the deflection field from leaking. In this embodiment, as a method of miniaturizing the size of the passage electrode 112, the first grid electrode 111, which is in a mesh shape and has the same potential as the passage electrode 112, is provided. By forming the first grid electrode 111 into the mesh shape, unnecessary potentials are prevented from leaking from the vicinity of a lower end of the passage electrode 112. Accordingly, this allows signal electrons to enter the deceleration space without influence on the primary electron beam 130.

In this embodiment, since the passage electrode 112, the first electrostatic field electrode 113 and the second electrostatic field electrode 115 are represented in a cylindrical shape, there is no limitation on these electrodes as long as they can form a desired potential in the following detection system operation.

According to this configuration, by controlling the voltage applied to the passage electrode 112 and the first electrostatic field electrode 113, the signal electrons with an arbitrary energy band can be guided to the secondary electron detector 110. That is, a part of the energy band of the backscattered electrons 131b also can be selectively detected by using the secondary electron detector 110.

### Second Embodiment

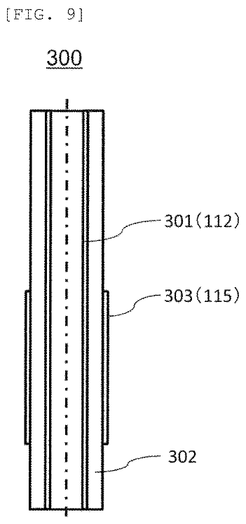

FIG. 7 is a schematic view of an SEM according to the second embodiment and FIG. 8 is a diagram in which secondary electron detectors according to the second embodiment are provided in four directions. In the second embodiment, the two first electrostatic field electrodes 113a and 113b are disposed on a side of the electron source 101 and a side of the objective lens 104. In the present embodiment, a space between these two first electrostatic field electrodes is defined as an “aperture”.

As in the first embodiment, when a high voltage is applied to the scintillator 201, a deflection field in the horizontal direction of a deceleration space is formed through the aperture between the first electrostatic field electrode 113a on the side of the objective lens and the first electrostatic field electrode 113b on the side of the electron source. Therefore, even in such a configuration, only the decelerated secondary electrons 131a can be collected in the deflection field, and the secondary electrons 131a can be selectively detected in the secondary electron detector 110.

### Third Embodiment

FIG. 8 is a schematic view of an SEM according to the third embodiment. In the third embodiment, a center pipe 300 is disposed in a passing path of the primary electron beam 130. FIG. 9 is a schematic cross-sectional view of the center pipe 300. The passage electrode 112 corresponds to an inner wall metal coating 301 of a tubular part. The inner wall metal coating 301 is covered on a high-resistance material 302. Further, a part of the high-resistance material 302 is covered by an outer wall metal coating 303 corresponding to the second electrostatic field electrode 115. In other words, the center pipe 300 is formed by applying the inner wall metal coating 301 to the insulating material 302 and applying the outer wall metal coating 303 to a part of the outer wall thereof. As the high-resistance material 302, for example, alumina, whose resistance value is controlled so as not to cause charging due to a collision of signal electrons, is used. The inner wall metal coating 301 and the outer wall metal coating 303 are made of any one of gold, silver and titanium, or combinations thereof. However, materials of the high-resistance material and the metal coating are not limited thereto.

The metal coating to which different voltages are applied is separated by the high-resistance material 302. The two metal coatings can be brought close to a thickness at which the high-resistance material 302 is not destroyed by a potential difference. Since this thickness can be made smaller than the distance between the electrodes when the insulating property is maintained by the space, it is possible to detect the secondary electrons 131a with a higher efficiency.

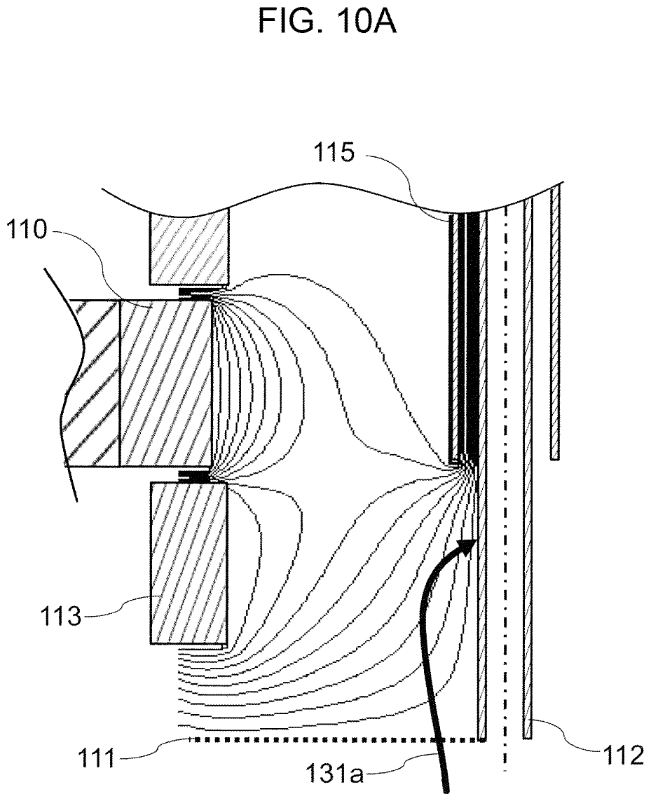

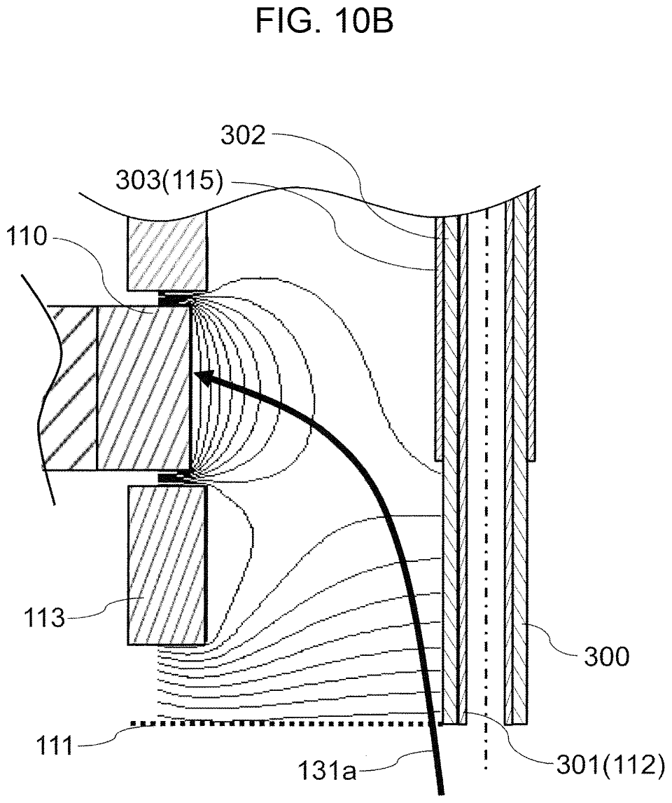

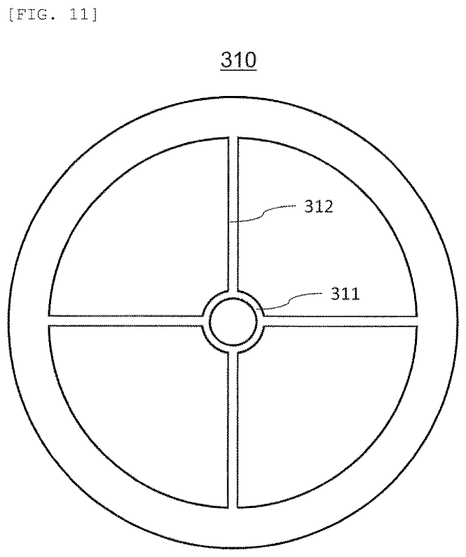

Further, the high-resistance materials 302 influences a potential distribution between the outer wall metal coating 303 and the first grid electrode 111. FIGS. 10A to 10B are schematic views of the potential distribution according to the third embodiment. FIG. 10A illustrates a case in which no high-resistance material 302 is provided and FIG. 10B illustrates a case in which the high-resistance material 302 is provided. The potential distribution shown in FIG. 10A draws equipotential lines almost parallel to the passage electrode 112 in the vicinity of the center pipe 300. Due to this potential distribution, the secondary electrons 131a which enter the vicinity of the passage electrode 112 are bent inward and collide with the inner wall metal coating 301. That is, the secondary electrons 131a are not detected by the secondary electron detector 110. On the other hand, as shown in FIG. 10B, since the high-resistance material 302 is provided, a minute current flows between the outer wall metal coating 303 and the first grid electrode 111, and the potential distribution on the surface of the high-resistance material is uniform. That is, the equipotential lines in the vicinity of the surface of the high-resistance material 302 are almost perpendicular to the center pipe 300. The uniform potential distribution causes secondary electrons 321 to travel straight in the vicinity of the center pipe 300 and to enter the deceleration space, thereby being detected by the secondary electron detector 110. Thus, by using a material having an appropriate resistivity for the high-resistance material 302, it is possible to detect the signal electrons with higher efficiency. The high-resistance material 302 preferably has a resistance value of 10¹³Ω or less.

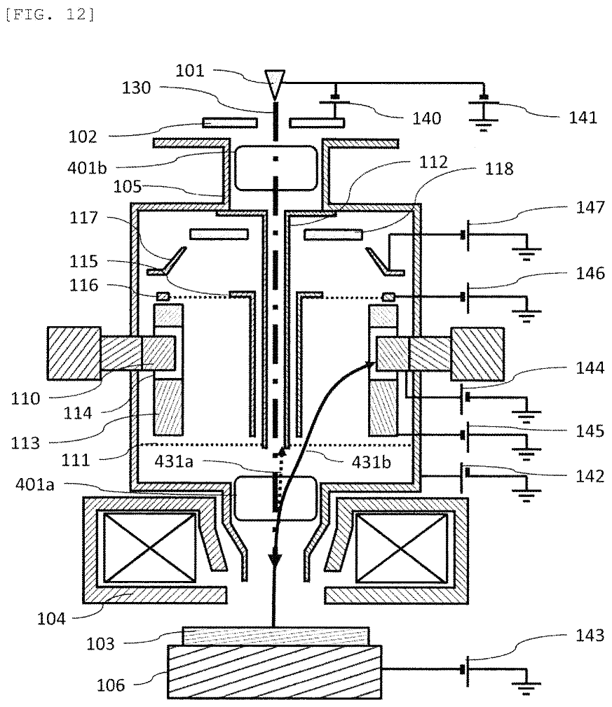

Abeam electrode 310 is in contact with the outer wall metal coating 303 of the center pipe 300. FIG. 11 is a schematic view of the beam electrode. The beam electrode 310 is provided to introduce a voltage into the outer wall metal coating 303. In addition, it is preferable to form a ring portion 311 and a beam portion 312 which are in contact with the outer wall metal coating 303 so as not to obstruct movements of the signal electrons. As described in the first and the second embodiments, an electrode having a mesh structure may be used for the purpose of preventing the potential from leaking from the backscattered electron detector 118.

In the third embodiment, an example of using a conversion electrode 121 is descibed as a detection method of the backscattered electrons 131b. Here, the backscattered electron detector 118, a third electrostatic field electrode 120 having an aperture, the second grid electrode 116 in contact with the third electrostatic electrode, and the conversion electrodes 121 which is in contact with the third electrostatic electrode and collides with a part of the backscattered electrons 131b are disposed on a side closer to the electron source 101 than the deceleration space. Further, a negative voltage power supply 148 which applies a voltage to the third electrostatic field electrode 120, the second grid electrode 116 and the conversion electrode 121 is also provided. The third embodiment describes an example that a plurality of backscattered electron detectors 118 are disposed, but there is no limitation on the number thereof.

Similarly to the first and the second embodiments, the backscattered electrons 131b with high energy which pass through the deceleration space collide with the conversion electrode 121, so that converted electrons 132 are generated. The converted electrons 132 are guided to a direction of the backscattered electron detector 118 due to the deflection field. Here, although there is no limitation on the method of forming the deflection field, the secondary electron detection, which is similar to the one in the first embodiment, can be easily realized by using an ET detector in the backscattered electron detector 118 and applying a high voltage to the scintillator.

Further, by applying a voltage lower than the first electrostatic field electrode 113 or the beam electrode 119 to the second grid electrode 116 and the third deceleration electrode 120, it is possible to prevent the secondary electrons 131a from passing through the deceleration space and being detected by the backscattered electron detector 118.

Moreover, although the conversion electrode 121 is in contact with the third electrostatic field electrode 120 and the same voltage is applied to the electrodes 121, it is not necessary that voltages of the third electrostatic field electrode 120 and the second grid electrode 116 are the same. For example, by applying a voltage lower than the third electrostatic field electrode 120 and the second grid electrode 116 (for example, a potential difference of 30 V) to the conversion electrode 121, it is possible to prevent the generated conversion electrons 132 from entering the deceleration space and being detected by the secondary electron detector 110.

### Fourth Embodiment

FIG. 12 is a schematic view of an SEM according to the fourth embodiment. A passage hole is provided in the passage electrode 112 to allow the primary electron beam 130 to pass therethrough. Therefore, secondary electrons 431a which enter the passage hole cannot be detected by the secondary electron detector 110. That is, it can be said that some signal electrons are lost. Further, depending on observation conditions of the SEM, the secondary electrons 431a are converged at the lower end of the passage electrode 112, and most of the secondary electrons 431a may enter the passage hole, which may significantly reduce the detection efficiency.

Therefore, a first deflector 401a is disposed closer to an objective lens than the lower end of the passage electrode 112. By operating the first deflector 401a with an appropriate strength, the track of the secondary electrons 431a which would normally enter the passage hole can be bent to the outside of the passage electrode 112. Secondary electrons 431b, which pass through the first grid electrode 111 and the track of which is bent, are detected by the secondary electron detector 110 according to the same principle as in FIG. 1. Thus, even under the condition that the secondary electrons are converged at the lower end of the passage electrode 112, high detection efficiency can be maintained.

Here, although there is no limitation on the configuration of the first deflector 401a, an orthogonal magnetic field device (hereinafter referred to as “E×B”) is preferable. The E×B is a means for deflecting only signal electrons without bending the primary electrons by using the fact that movement directions of the primary electrons and the signal electrons are reversed. The specific structure includes a pair of electrodes facing each other across the primary electrons and a pair of magnetic poles facing each other across the primary electrons in a direction going along the pair of electrodes. The pair of electrodes and the pair of magnetic poles form an electric field and a magnetic field which respectively impart a deflecting action to the primary electrons and the signal electrons.

When the E×B is operated, a magnetic field is set to provide a deflecting action in the opposite direction in the same amount so as to cancel out the deflecting action provided by the electric field to the primary electrons. Therefore, the primary electrons are not influenced by the deflecting action from the E×B. On the other hand, since the movement direction of the signal electrons is opposite to that of the primary electrons, the direction of the deflecting action received from the magnetic field is opposite to the primary electrons. That is, for the signal electrons, deflection due to the electric field and deflection due to the magnetic field act in the same direction. According to the above principle, only the signal electrons can be deflected without deflecting the primary electrons by the E×B.

Since the present embodiment applies the deceleration optical system, a relatively large deflection action is required when the signal electrons are deflected. Therefore, it is more desirable to use the E×B as the first deflector 401a in order to mitigate the influence on the primary electron beam 130.

Further, in this embodiment, the second deflector 401b is disposed closer to the electron source than an upper end of the passage electrode 112. The purpose of the second deflector 401b is to reduce an increase in aberration of the primary electron beam 130. The first deflector 401a is a cause of the increase in aberration to be reduced. Even when the E×B is used as the first deflector 401a, dispersion of the track occurs due to variations in energy of the primary electron beam 130, thereby resulting in poor aberration. Therefore, in order to reduce the dispersion of the track, an E×B is disposed as the second deflector 401b on the side of the electron source, and an electromagnetic field is formed in a direction opposite to the first deflector 401a. By these two E×B, a track dispersion of the primary electron beam 130 is canceled out, and the increase in aberration can be reduced.

### Fifth Embodiment

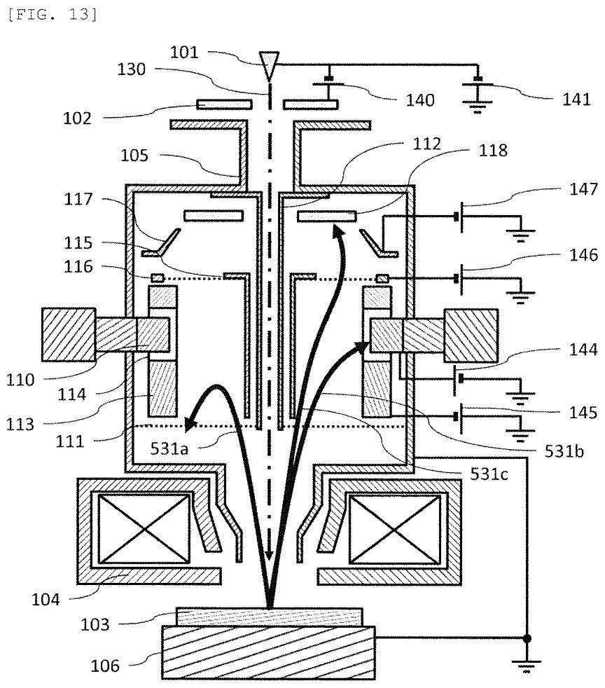

FIG. 13 is a schematic view of an SEM according to the fifth embodiment. Here, no deceleration optical system is applied. Hereinafter, the SEM to which the deceleration optical system is not applied is referred to as a non-deceleration optical system SEM. In case of the non-deceleration optical system SEM, it is already known a method of deflecting only secondary electrons and separately detecting backscattered electrons. Also in the fourth embodiment, it is possible to selectively detect only the secondary electrons by setting the first electrostatic field electrode 113, the second electrostatic field electrode 115 and the second grid electrode 116 to the same potential (ground potential) as the sample.

In addition, the energy of the backscattered electrons can also be discriminated. In the non-deceleration optical system SEM, since the signal electrons are not accelerated, secondary electrons 531a travel in the SEM with low energy. Here, when the negative voltage is applied to the first electrostatic field electrode 113, the secondary electrons 531a with a low energy cannot get over the electrostatic potentials formed by the negative voltage, and return back. Here, a part 531b whose energy is relatively low in the backscattered electrons is decelerated in the deceleration space to an extent of energy at which the part 531b can be collected by the deflecting field, and is detected by the secondary electron detector 110. Further, apart 531c whose energy is relatively high in the backscattered electrons passes through the deflection field even if it is decelerated by the deceleration space and is detected by the backscattered electron detector 118. Here, a detector which detects a backscattered electron with a certain energy varies depending on voltages applied to the first electrostatic field electrode 113, the second electrostatic field electrode 115 and the second grid electrode 116. Therefore, by controlling these voltages, the energy band of the backscattered electrons detected by the secondary electron detector 110 and the backscattered electron detector 118 can be controlled.

Thus, even in the non-deceleration optical system SEM, it is possible to discriminate and detect the secondary electrons and backscattered electrons and to discriminate and detect the energy of backscattered electrons.

### Sixth Embodiment

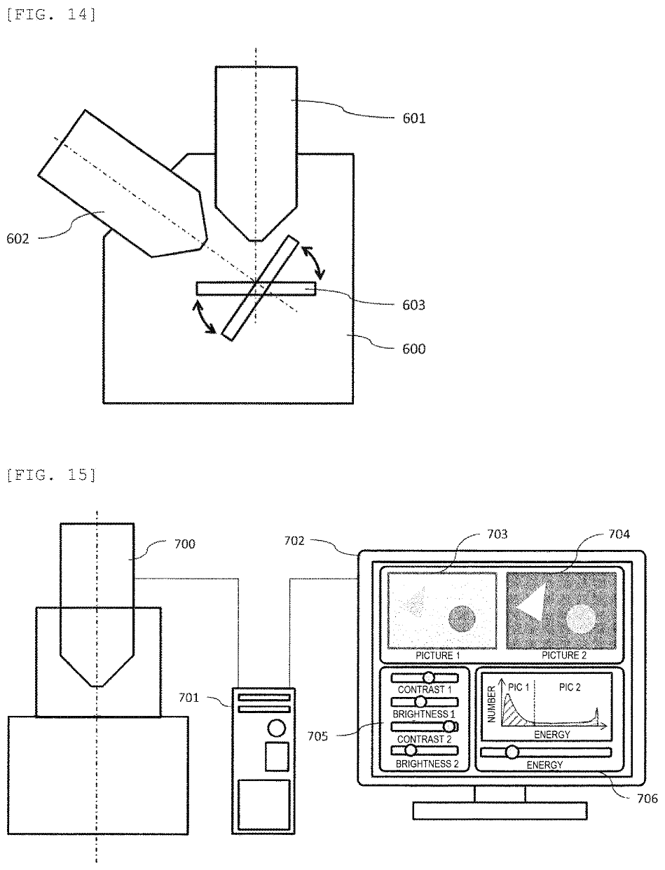

FIG. 14 is a schematic view of an FIB-SEM. The FIB-SEM includes an SEM body 601 and an FIB body 602 shown in FIGS. 1, 6, 8, 12 and 13 in a sample chamber 600 in which two bodies can be disposed. Even in such a configuration in which two bodies are disposed, secondary electrons can be efficiently detected without influence on the primary electron beam and a primary ion beam based on the principle described above. Here, there is no limitation on the arrangement direction of the two bodies. In FIG. 14, the SEM body 601 is disposed perpendicular to the sample chamber, and the FIB body 602 may also be disposed perpendicular to the sample chamber. Further, optical axes of the two bodies may be disposed to be perpendicular to each other. When the optical axes of the two bodies are disposed in an inclined manner, the sample holder on which a sample 603 is disposed may include a mechanism which rotates so that the sample 603 can be vertically disposed with respect to the SEM body 601 and the FIB body 602.

### Seventh Embodiment

FIG. 15 illustrates an example of a GUI screen (display unit). This embodiment includes an SEM 700 shown in FIGS. 1, 6, 8, 12 and 13, a PC 701 which controls the SEM 700, and a monitor 702 which displays an operation screen. A scanning image 703 obtained from a secondary electron detector and a scanning image 704 obtained from a backscattered electron detector are displayed on the monitor 702. As described above, since secondary electrons and backscattered electrons reflect different information of the sample in the image, the two images have different contrasts.

In general, the SEM has a function of adjusting brightness and contrast of scanning images. In this embodiment, since two images can be obtained at the same time, it is desired that the brightness and contrast of these two images can be changed independently and simultaneously. Thus, the monitor 702 includes an operation screen (first input unit) 705 which adjusts the brightness and/or contrast gradation of each of the two images. Further, the monitor 702 includes an operation screen (second input unit) 706 which operates an energy threshold of signals obtained by the two detectors. Since the energy threshold is selected on the operation screen, the potential of the deceleration space is controlled, so as to change the ratio of the signal electrons drawn into the econdary electron detector and the signal electrons which pass through the backscattered electron detector. Since a scroll bar is applied to these operations, it is possible to easily and quickly perform the operation.

This function allows a user to select the desired sample information more directly. This is because the potential of the deceleration space is not important for a user who is clear about desired sample information, and instead the energy band of the obtained signal electrons is important. Therefore, instead of operating the potential of the deceleration space or the voltage applied to the electrode forming the deceleration space, it is possible to make the user's image much more nice to understand by operating the energy band of the signal electrons expected to be actually detected as in the present embodiment.

According to the above embodiments, it is possible to achieve both the aberration reduction of the primary electron beam and the high efficiency detection of the secondary electrons.

### REFERENCE SIGN LIST

101 Electron source
102 Extraction electrode
103 Sample
104 Objective lens
105 Boosting electrode
106 Sample holder
110 Secondary electron detector
111 First grid electrode
112 Passage electrode
113 First electrostatic field electrode
114 Aperture
115 Second electrostatic field electrode
116 Second grid electrode
117 Track control electrode
118 Backscattered electron detector
130 Primary electron beam
131a Secondary electrons
131b Backscattered electrons
140 Extraction power supply
141 Acceleration power supply
142 Boosting power supply
143 Retarding power supply
144 Detector power supply
145 First deceleration power supply
146 Second deceleration power supply
147 Track control power supply

1. A charged particle beam device comprising:
a charged particle beam source which emits a primary charged particle beam;
an objective lens which focuses the primary charged particle beam on a sample;
a passage electrode which is formed of a metal material and is disposed between the charged particle beam source and a tip end of the objective lens;
a first detector which detects a secondary charged particle emitted from the sample; and
an electrostatic field electrode which is electrically insulated from the passage electrode, wherein
the passage electrode is formed such that the primary charged particle beam passes through an inside of the passage electrode, and
the electrostatic field electrode is formed to cover an outer periphery of the passage electrode.

2. The charged particle beam device according to claim 1, wherein
the electrostatic field electrode includes an aperture on a side wall, and
a sensitive surface of the first detector faces the aperture.

3. The charged particle beam device according to claim 1, wherein
the electrostatic field electrode is disposed on a side of the objective lens and a side of the charged particle source, respectively,
the electrostatic field electrode includes an aperture between the electrostatic field electrode on the side of the objective lens and the electrostatic field electrode on the side of the charged particle source, and
a sensitive surface of the first detector faces the aperture.

4. The charged particle beam device according to claim 2, wherein
the electrostatic field electrode includes a first electrostatic field electrode on a side including the aperture and a second electrostatic field electrode disposed between the first electrostatic field electrode and the passage electrode,
the passage electrode and the second electrostatic field electrode are electrically insulated, and
the first electrostatic field electrode is formed to cover an outer periphery of the second electrostatic field electrode.

5. The charged particle beam device according to claim 1, further comprising:
a first grid electrode which is disposed between the objective lens and the detector and has the same potential as the passage electrode.

6. The charged particle beam device according to claim 4, further comprising:
a high-resistance material in contact with the passage electrode and the second electrostatic field electrode.

7. The charged particle beam device according to claim 6, wherein
the high-resistance material has a resistance value of 10¹³Ω or less.

8. The charged particle beam device according to claim 7, further comprising:
a second grid electrode in contact with the second electrostatic field electrode.

9. The charged particle beam apparatus according to claim 2, wherein
the electrostatic field electrode includes a plurality of the apertures, and detectors are provided corresponding to each of the apertures.

10. The charged particle beam device according to claim 3, further comprising:
a plurality of detectors.

11. The charged particle beam device according to claim 10, further comprising:
a system which adds and/or subtracts signals obtained by the plurality of detectors.

12. The charged particle beam device according to claim 2, wherein
the sensitive face is a scintillator which converts the secondary charged particle into light
the first detector includes a photodetector which detects converted light,
the charged particle beam device includes a high voltage power supply which applies a positive voltage to the scintillator, and
a part of the secondary charged particle decelerated by the electrostatic field electrode via the positive voltage of the scintillator is deflected to the first detector.

13. The charged particle beam device according to claim 1, further comprising:
a deflector which deflects the secondary charged particle to the first detector.

14. The charged particle beam device according to claim 1, further comprising:
a second deflector which deflects the secondary charged particle between the passage electrode and the objective lens.

15. The charged particle beam device according to claim 1, further comprising:
a second detector between the first detector and the charged particle beam source to detect a part of the secondary charged particle not detected by the first detector.

16. The charged particle beam device according to claim 15, further comprising:
a conversion electrode which collides with the part of the secondary charged particle not detected by the first detector, wherein
the second detector detects a charged particle generated at the conversion electrode by a collision of the secondary charged particle.

17. The charged particle beam device of claim 15, further comprising:
a track control electrode between the second detector and the first detector.

18. The charged particle beam device according to claim 1, further comprising:
a display unit which displays a charged particle image, wherein
the display unit includes a first input unit which sets a gradation of brightness and/or contrast of the charged particle image and/or a second input unit which sets an energy band of the secondary charged particle detected by the detector.

19. A charged particle beam device comprising:
a charged particle beam source which emits a primary charged particle beam;
an objective lens which focuses the primary charged particle beam on a sample,
a passage electrode which is formed of a metal material and is disposed between the charged particle beam source and a tip end of the objective lens;
a first detector which detects a secondary charged particle emitted from the sample; and
an electrostatic field electrode which is electrically insulated from the passage electrode, wherein
the primary charged particle beam passes through an inside of the passage electrode,
a deceleration space is formed between the passage electrode and the detector, which decelerates the secondary charged particle emitted from the sample to an potential extent of the sample,
a deflection field is formed in the deceleration space, and
a part of the secondary charged particle decelerated in the deceleration space is deflected to the detector by the deflection field.

20. The charged particle beam device according to claim 19, wherein
potential of the deceleration space is adjustable such that energy of the secondary charged particle detected by the first detector is 50 eV or less in the deceleration space.
